(19) United States
(12) Patent Application Publication
(10) Pub. No.: US 2016/0095402 A1
(43) Pub. Date: Apr. 7, 2016

(54) UNIVERSAL CASE WITH MAGNETIC OVERLAP

(71) Applicant: Targus Group International, Inc., Anaheim, CA (US)

(72) Inventors: Dahlia Saad, Trabuco Canyon, CA (US); Michael Alan Sexton, Ladera Ranch, CA (US); Alexander Moss Farkas, Los Angeles, CA (US); Andrew Norman Corkill, Riverside, CA (US)

(21) Appl. No.: 14/874,980

(22) Filed: Oct. 5, 2015

Related U.S. Application Data
(60) Provisional application No. 62/059,310, filed on Oct. 3, 2014.

(51) Int. Cl. A45C 11/00; A45C 13/10; H05K 5/02; A45C 13/00; H05K 5/03

(52) U.S. Cl. CPC A45C 11/00; A45C 13/005; H05K 5/03; H05K 5/0226; A45C 13/1069; A45C 2011/003

(57) ABSTRACT

A universal case for a portable electronic device (PED) includes a rear panel, a front panel, a flexible member, and a flap configured to secure the universal case in a closed position. The flap and rear panel may have magnetic portions that can engage in any of a plurality of positions to close the universal case. The flap may be coupled to the front panel by a flexible member. In an embodiment, when the magnetic portions engage in a first position the flexible member partially overlaps the rear panel, and when the magnetic portions engage in a second position the flexible member is offset from the rear panel. A maximum distance between the rear panel and the front panel is greater when in the second position than when in the first position. Thus, the universal case may be used to secure PEDs having various lengths, widths, aspect ratios, and thicknesses.

### RELATED APPLICATIONS

This application claims priority to provisional patent application Ser. No. 62/059,310 filed on Oct. 3, 2014 and which is incorporated herein by reference.

### TECHNICAL FIELD

This disclosure generally relates to cases for portable electronic devices.

### BRIEF DESCRIPTION OF THE DRAWINGS

Non-limiting and non-exhaustive embodiments of the disclosure are described, including various embodiments of the disclosure with reference to the figures, in which:

FIG. 1 is a front perspective view of an embodiment of a universal case in a closed position and a flap in a first position.

FIG. 2 is a front perspective view of an embodiment of a universal case in a closed position and the flap in a second position.

FIG. 3 is a side perspective view of an embodiment of a universal case in a closed position and the flap in a first position.

FIG. 4 is a side perspective view of an embodiment of a universal case in a closed position and the flap in a second position.

FIG. 5 is a side perspective view of an embodiment of a universal case in an open position with the rear panel positioned to support a PED in an inclined position.

FIG. 6 is a side perspective view of an alternative embodiment of a universal case in an open position with the rear panel positioned to support a PED in an inclined position.

FIG. 7 is a side perspective view of an embodiment of a universal case in an open position with the front panel positioned to support a PED in an inclined position.

FIG. 8 is a front perspective view of an embodiment of a universal case in an open position.

FIG. 9 is a rear perspective view of an embodiment of a universal case in an open position.

In the following description, numerous specific details are provided for a thorough understanding of the various embodiments disclosed herein. The embodiments disclosed herein can be practiced without one or more of the specific details, or with other methods, components, materials, etc. In addition, in some cases, well-known structures, materials, or operations may not be shown or described in detail in order to avoid obscuring aspects of the disclosure. Furthermore, the described features, structures, or characteristics may be combined in any suitable manner in one or more alternative embodiments.

### DETAILED DESCRIPTION

The present disclosure provides various embodiments of universal cases for securing, protecting, and/or supporting portable electronic devices (PEDs). According to various embodiments, a universal case may be configured to secure PEDs having various dimensions. For example, a single universal case may be configured to secure a tablet device with a 10-inch diagonal display or a tablet device with an 8-inch diagonal display. Similarly, a single case may be configured to secure tablet devices and/or other PEDs with varying thicknesses and/or aspect ratios. A universal case may include a pivotally coupled rear or first panel and a second or front panel that may be selectively opened or closed. The universal case may be secured in a closed position by a fastening mechanism. The fastening mechanism may have the ability to define a maximum distance between the rear panel and the front panel in order to accommodate PEDs with varying thicknesses. The maximum distance may be the greatest distance between the front and rear panel that is possible without adjusting the fastening mechanism or altering the configuration of the case (e.g., by damaging, destroying, or removing one or more elements of the case).

According to various embodiments, a universal case may use a flap as a fastening mechanism. The universal case may include a front panel and rear panel pivotally coupled along one edge. A user may open the universal case by grasping the front and rear panels along an open edge (i.e., the edge of the front and rear panels opposite a pivotally coupled edge). The flap may be pivotally coupled to the opening edge of the front panel by a flexible member such as a flexible strip.

Further, the flap may be able to secure the universal case closed by engaging with the rear panel via magnets, clasps, buttons, snaps, or the like in a plurality of positions. When the flap is in a first closed position the flexible member may at least partially overlap the rear panel, and when the flap is in a second closed position the flexible strip may be offset from the rear panel (e.g., the flexible strip does not overlap the rear panel). In other embodiments, the flexible strip may overlap the rear panel in both first and second closed positions. When the flap is in the first closed position the flexible member may include more overlap than when the flap is in the second closed position. In an embodiment, the distance between the rear panel and the front panel is greater when the flap is in the second position than when the flap is in the first position. This is because the maximum distance may be mechanically limited to the amount of the flexible member that is not overlapping. The flexible member may be the only feature on the universal case's opening edge that limits or allows adjustment of the distance between the rear panel and front panel.

For example, the flap and/or the rear panel may include multiple magnetic strips or one wide magnet to allow the flap to engage with the rear panel in a plurality of positions. A first magnetic portion may be embedded on the inside of or attached to the surface of the rear panel adjacent the open edge. The first magnetic portion may be comprised of multiple magnetic strips or one wide magnet. The second magnetic portion may be embedded on the inside of, attached to the surface of, or rotatably coupled to the flap. One of the magnetic portions may use a ferrous metal instead of a permanent magnet. The second magnetic portion may also be composed of magnetic strips or one wide magnet. The first magnetic portion may be longer than the second magnetic portion. The first magnetic portion has a length extending from the open edge that is greater than the length of the second magnetic portion extending from the flexible member.

The second magnetic portion can engage the first magnetic portion along different portions of the first magnetic portion's length (or to different magnetic strips) to provide the various flap positions and case thicknesses previously discussed. The plurality of positions may range from the open edge to the opposite end of the first magnetic portion. The positions of multiple magnets and/or the size of a single magnets may be selected based on an expected thickness of PEDs to be used with the universal case. A user may slide the second magnetic portion along the length of the first magnetic portion to secure a closed position.

The front panel and rear panel may cover and provide protection for an enclosed PED. The PED may have a display or front side, and a rear or back side comprising a side opposite the display. The rear panel may cover and protect the PED's rear side. A PED may be secured to the rear panel via a support structure such as elastics, magnets, adhesives, frictional engagement, mechanical obstruction, or the like. The front panel may selectively cover and protect a PED's display side.

Additionally, various embodiments may use the rear panel to support a PED in an inclined position. The PED may be supported in a portrait and/or landscape position. Some embodiments may include an attached stand for support. Other embodiments may include a folding rear panel for support. Such a folding rear panel may be comprised of an upper section coupled to the support structure and a lower section pivotally coupled to the upper section. The lower section may be configured to pivot away from the support structure, such that the lower section supports the support structure in an inclined position.

The upper section and lower section may be part of the rear panel. The upper section and lower section may be made out of the same material as the front panel. The upper section and lower section may be coupled by a hinge, flexible material, or the like. The upper section may include the portion along the opening edge and may be coupled along its entirety to the support structure. The lower section may be rotatably coupled to both the upper section and the front panel. The lower section can swing away from or toward the support structure via its coupling with the upper section. Similarly, the support structure may swing away from or toward the lower section. A folding point may be created where the lower section and front panel are coupled. The folding point may rest on a support surface and maintain the support structure in an inclined position. In an embodiment, the support structure's degree of incline is defined by how far the lower section is rotated away from the support structure. The farther away the lower section swings, the more parallel with the support surface the support structure becomes. The lower section and support structure may be able to move between a first position in which the support structure is nearly vertical, and a second position in which the support structure is nearly horizontal.

A PED may be secured to the support structure. The support structure may be substantially rigid so the weight of a secured PED will not deform the support structure and cause the case to fall out of an inclined position. The support structure's width and length may be selected based on expected widths and lengths of PEDs to be used with the case. When in an inclined position, the support structure's edge opposite the universal case's opening may rest on a support surface and maintain the PED in an inclined position.

A “portable electronic device” (PED) as used throughout the specification may include any of a wide variety of electronic devices. Specifically contemplated and illustrated are tablet-style electronic devices, including, but not limited to, electronic readers, tablet computers, tablet PCs, mini tablets, phablets, cellular phones (including smart phones), interactive displays, video displays, touch screens, touch computers, etc.

Reference throughout this specification to “one embodiment” or “an embodiment” means that a particular feature, structure, or characteristic described in connection with the embodiment is included in at least one embodiment. Thus, the appearances of the phrases “in one embodiment” or “in an embodiment” in various places throughout this specification are not necessarily all referring to the same embodiment.

Additionally, any of a wide variety of materials and manufacturing methods may be used to produce the various components of the presently described case for portable electronic devices. For example, a universal case and/or the stand may utilize various plastics, rubbers, nylons, glasses, fabrics, leathers, and/or other suitable materials.

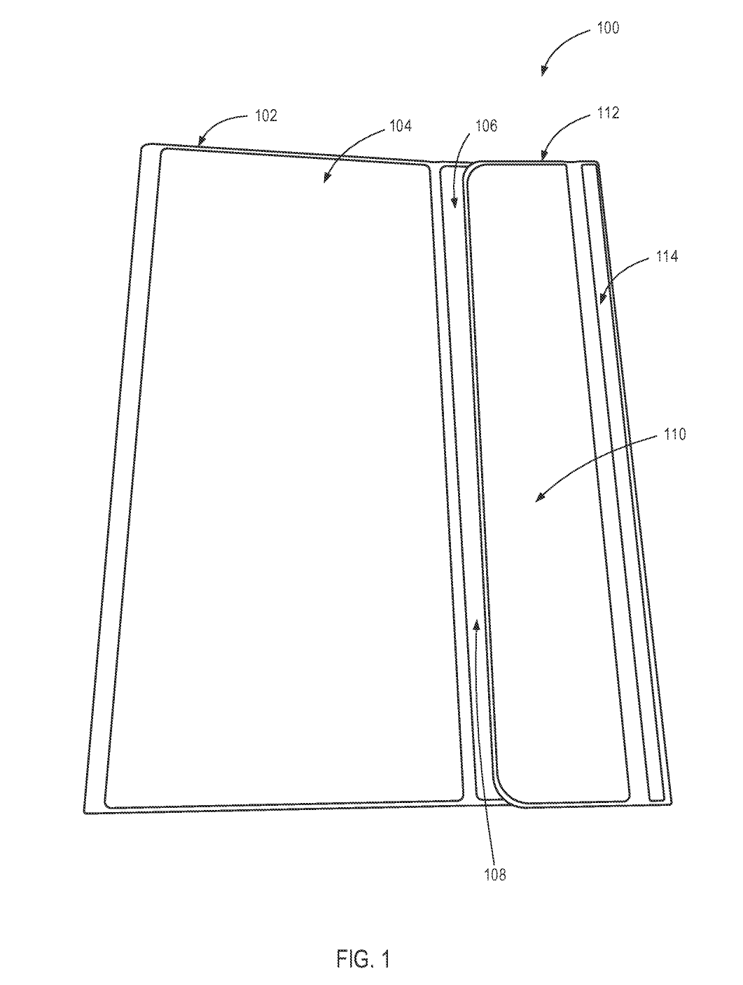

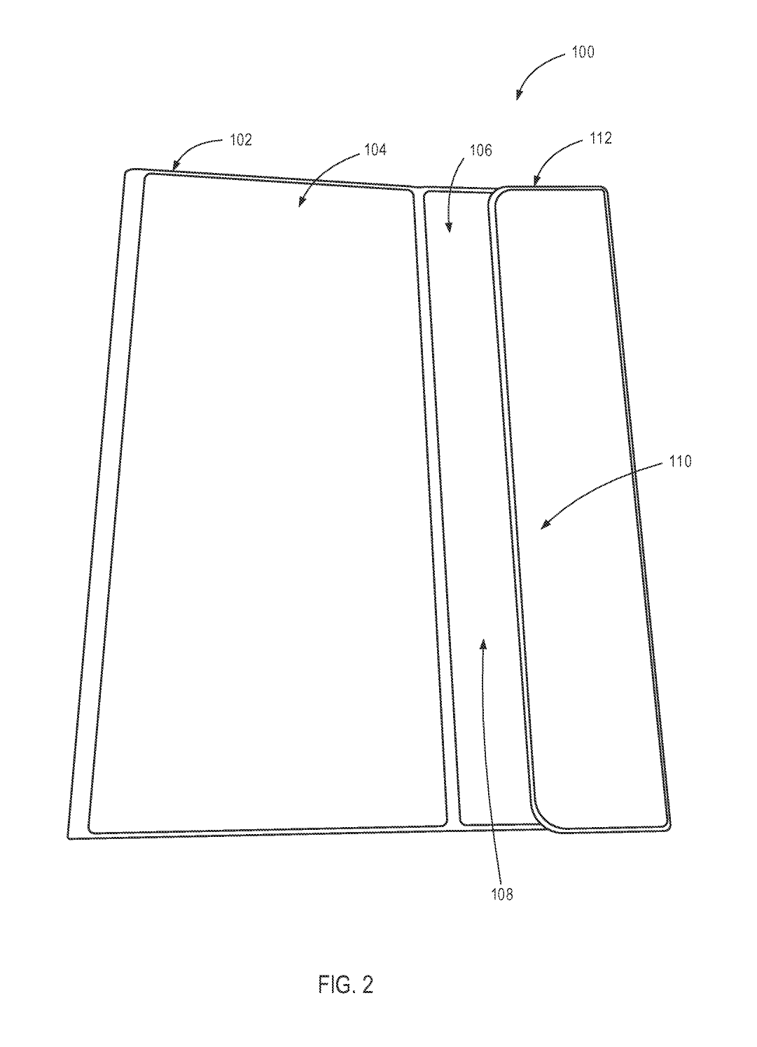

FIGS. 1-2 illustrate front perspective views of an embodiment of a universal case 100 in a closed position, and a flap 112 engaged in a first position and a second position, respectively. The universal case 100 may include a rear panel 102 comprised of an upper section 106 and a lower section 104. The upper section 106 defines the portion near the opening edge. A substantial part of the upper section 106 may include a first magnetic portion 108. The upper section 106 may be comprised of a smaller area of the rear panel 102 than the lower section 104. The universal case 100 may also include the flap 112 with dimensions similar to the upper section 106. A substantial part of the flap 112 may include a second magnetic portion 110. The first magnetic portion 108 and second magnetic portion 110 may be comprised of a single magnetic panel, one or more magnetic strips, or one or more magnets.

As illustrated, the second magnetic portion 110 can engage the first magnetic portion 108 in any of a plurality of positions to close the universal case 100. The second magnetic portion 110 may engage the first magnetic portion 108 anywhere along the first magnetic portion's 108 length. The flap 112 that includes the second magnetic portion 110 may be coupled to a flexible member 114. The flexible member 114 may be non-magnetic. As illustrated, the length of the first magnetic portion 108 extending from an open edge is greater than the length of the second magnetic portion 110 extending from the flexible member 114. The difference in lengths allows for variable positioning of the second magnetic portion 110 relative to the first magnetic portion 108. When the second magnetic portion 110 is in a first closed position, as illustrated in FIG. 1, the flexible member 114 at least partially overlaps the rear panel's 102 upper section 106. Whereas, when the second magnetic portion 110 is in a second position, as illustrated in FIG. 2, the flexible member 114 is offset from the rear panel 102.

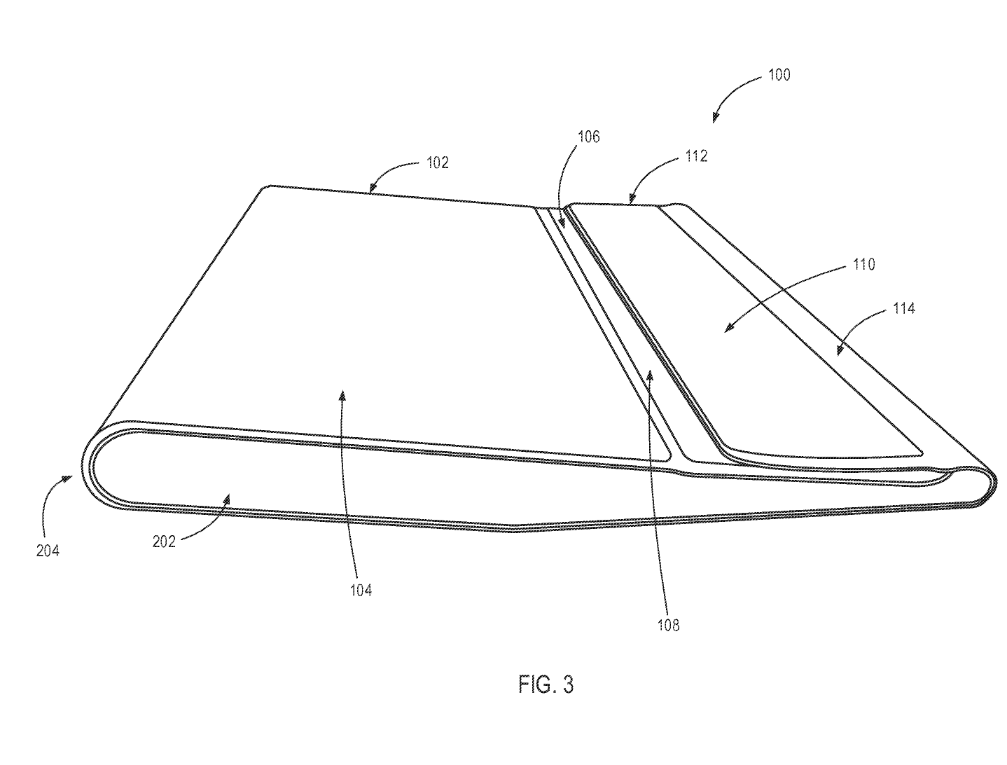

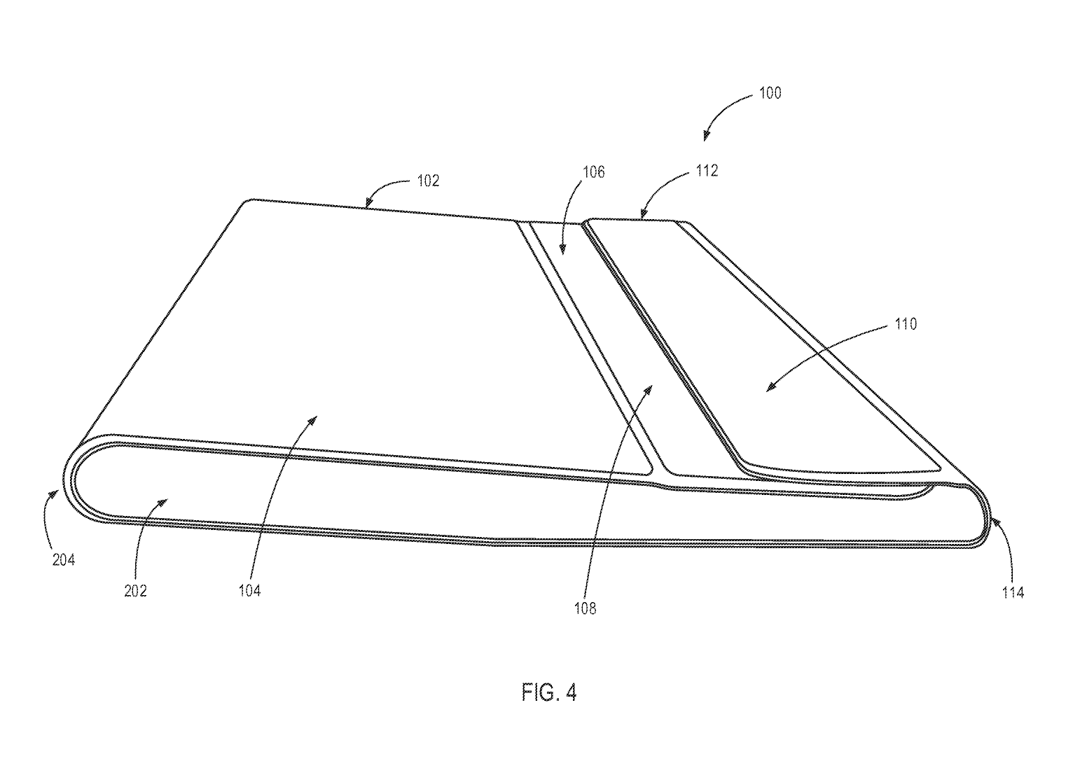

FIGS. 3-4 illustrate side perspective views of an embodiment of a universal case 100 in a closed position, and a flap 112 engaged in a first position and a second position, respectively. As illustrated, the flap 112 may be coupled to a flexible member 114 which is coupled to a front panel 202. The front panel 202 may selectively cover a PED's display side and may include features configured to protect the display of the PED from scratches and damage. For example, an interior of the front panel 202 may be lined with a microfiber material to prevent scratches.

The flap's 112 position determines the distance between the front panel 202 and a rear panel 102. When the flap 112 is in a first position, as illustrated in FIG. 3, the flexible member 114 at least partially overlaps the rear panel 102. When the flexible member 114 overlaps the rear panel 102, the distance between the front panel 202 and the rear panel 102 is limited by the non-overlapping portion of the flexible member 114. When the flap 112 is in a second position, as illustrated in FIG. 4, the flexible member 114 is offset from the rear panel 102. Because the flexible member 114 is offset from the rear panel 102 in the second position, the distance between the front panel 202 and rear panel 102 is defined by the entire length of the flexible member 114. Thus, when the flexible member 114 is offset from the rear panel 102, the distance between the front panel 202 and rear panel 102 is greater than when the flap 112 is in the first position. Consequently, a user may configure the universal case 100 to secure different PEDs with varying thicknesses by adjusting how much of the flexible member 114 overlaps the rear panel 102.

The front panel 202 and the rear panel 102 are joined together at a closed end 204, which may include a folding point, flexible material, hinge, U-shaped member, or the like. In one embodiment, the closed end 204 may be expandable to accommodate PEDs of various thickness.

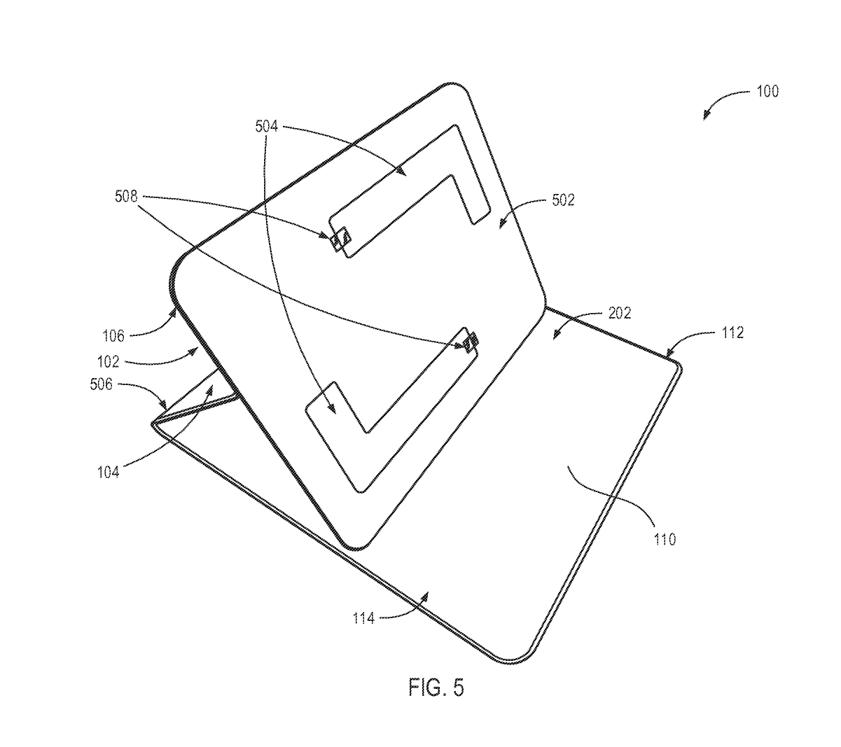

FIG. 5 is a side perspective view of an embodiment of a universal case 100 in an open position with a rear panel 102 positioned to support a PED in an inclined position. The universal case 100 may include a support structure 502 that couples to a PED via securing mechanisms 504. The rear panel's 102 upper section 106 may be coupled along its entirety to the support structure 502, and the rear panel's 102 lower section 104 may be pivotally coupled to the upper section 106 and a front panel 202.

The support structure 502 may use securing mechanisms 504 such as frictional holder, elastics, magnets, adhesives, or mechanical obstruction to couple with a PED. Certain securing mechanisms 504 may couple PEDs having various thicknesses to the support structure 502. If, as illustrated, adhesive strips are used, protective covers may be placed on the adhesive strips to ensure the adhesive strips retain their stickiness. Easy pull tabs 508 may be placed on the protective covers for easy removal.

The lower section 104 is configured to pivot away from the support structure 502, such that the lower section 104 supports the support structure 502, and any secured PED, in an inclined position. A folding point 506, created where the lower section 104 and front panel 202 are coupled, may rest on a support surface and maintain the support structure 502 in an inclined position. The support structure's 502 edge may rest on the front panel 202. The front panel 202 may include features to keep the support structure 502 from slipping while in an inclined position such as a high friction surface, grooves (e.g., grooves configured to engage with the support structure 502), or the like.

The support structure's 502 degree of incline is defined by how far the lower section 104 is rotated away from the support structure 502. In some embodiments, the lower section 104 may rotate between a first position in which the lower section 104 supports the support structure 502 in an inclined position and a second position in which the lower section 104 lies flush against the support structure 502. The display side may be in contact with the front panel 202 in the second position. When the lower section 104 is in the second position, the universal case 100 may be compact for easy storage.

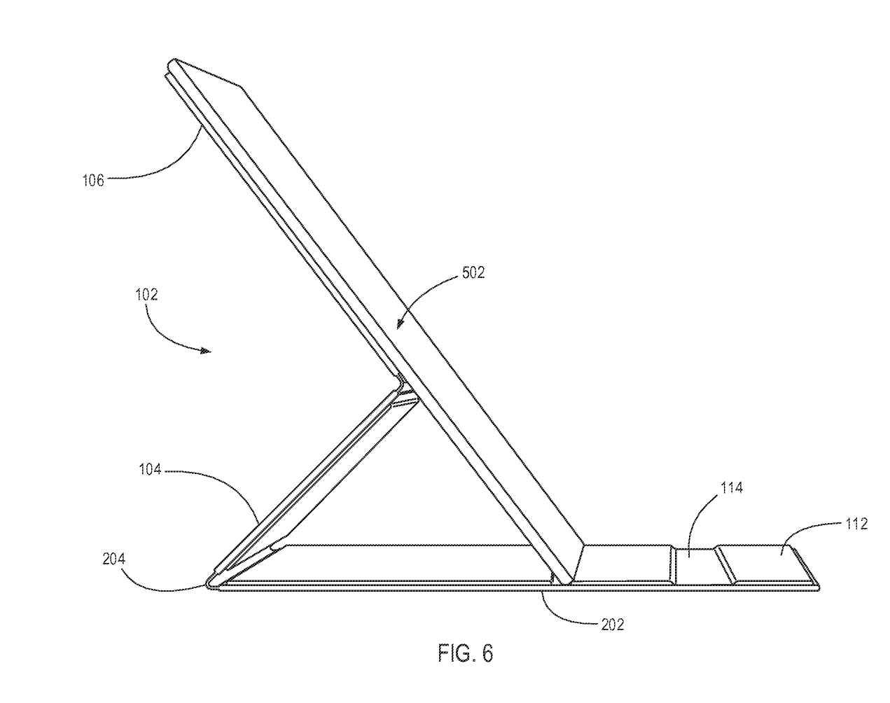

FIG. 6 is a side perspective view of an alternative embodiment of a universal case 100 in an open position with a front panel 202 laid flat on a horizontal surface. A lower section 104 of a rear panel 102 is pivoted away from a support structure 502, such that the lower section 104 supports the support structure 502, and any secured PED, in an inclined position. The support structure 502 is secured to an upper section 106 and may be embodied as a holder or tray to receive and frictionally retain the PED. In one embodiment, the support structure 502 may be configured to provide rotational movement of the PED from landscape to portrait orientations. Embodiments of rotational support structure are disclosed in U.S. Pat. Nos. 8,746,449 and 8,783,458, which are incorporated herein by reference. As illustrated, the support structure 502 may rest on the interior of the front panel 202.

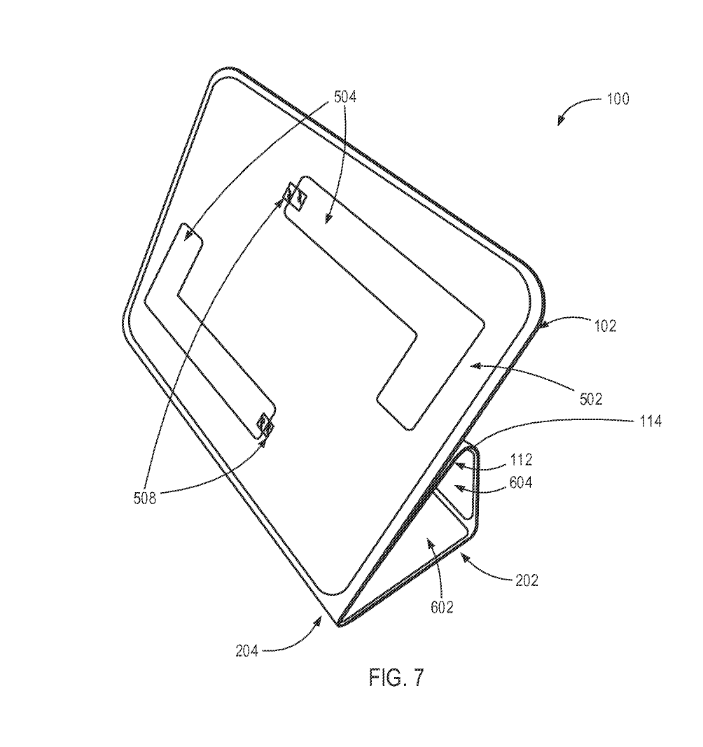

FIG. 7 is a side perspective view of an embodiment of a universal case 100 in an open position with a front panel 202 positioned to support a PED in an inclined position. The front panel 202 may include first and second sections 602, 604. The first section 602 may be pivotally coupled to a rear panel 102 at a closed end 204 such that the first section 602 may pivot between a first position in which the front panel 202 covers a secured PED's display, and a second position in which the first section 602 rests on a support surface behind the rear panel 102. The second section 604 may be pivotally coupled to the first section 602 and a flexible member 114. The second section 604 and a flap 112 may be positioned behind the rear panel 102, such that the second section 604 and flap 112 support the rear panel 102 in an inclined position as the first section 602 rests on the support surface.

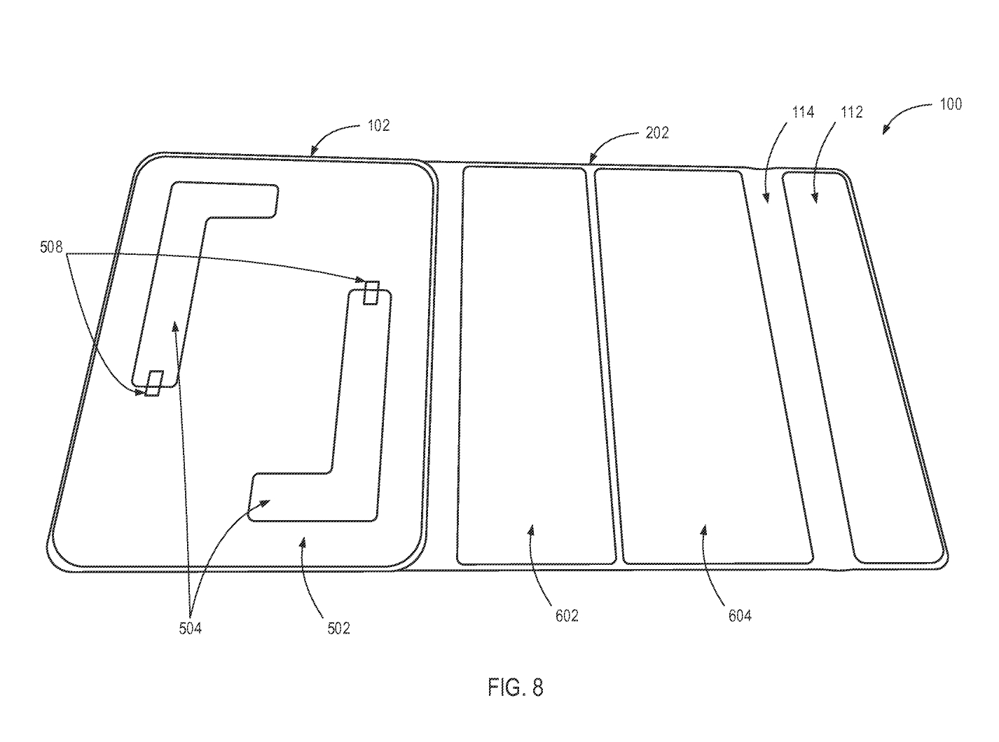

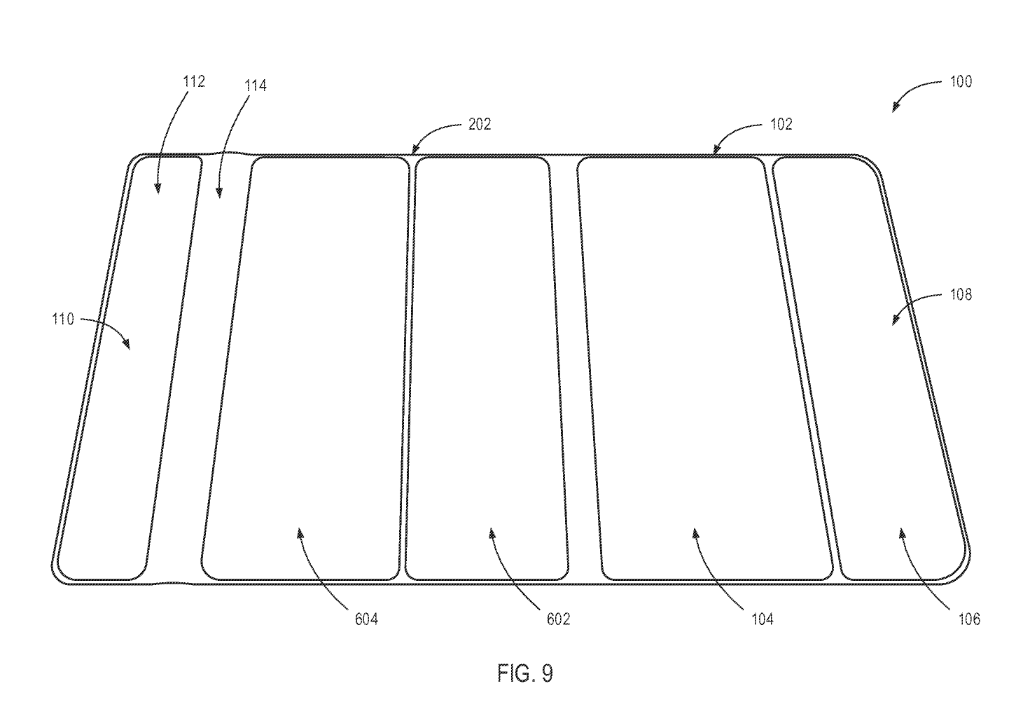

FIGS. 8-9 illustrate a front and rear view of an embodiment of a universal case 100 in an open position. As illustrated, the universal case 100 may be in one of three positions: storage, inclined or display, and open. In a storage position, the universal case 100 may enclose and protect a PED. In an inclined or display position, the universal case 100 may provide an ergonomic viewing angle for a user. Finally, in an open position, all of the pieces of the universal case 100 may lie parallel with a supporting surface.

The above description provides numerous specific details for a thorough understanding of the embodiments described herein. However, those of skill in the art will recognize that one or more of the specific details may be omitted, or other methods, components, or materials may be used. In some cases, operations are not shown or described in detail. Additionally, features or elements described in conjunction with any one embodiment may be adapted for use with and/or combined with the features of any other embodiment.

What is claimed:

1. A case for a portable electronic device having a display side and a back side, the case comprising:
a first panel including,
an interior surface to contact the portable electronic device,
an exterior surface, and
a first magnetic portion disposed adjacent the exterior surface;
a second panel pivotally coupled to the first panel to transition the case from an open position to a closed position wherein the portable electronic device is disposed between the first and second panels;
a flexible member coupled to the second panel; and
a flap pivotally coupled to the flexible member, the flap including a second magnetic portion,
when the case is in a first closed position, the flexible member at least partially overlaps the first panel and the second magnetic portion engages the first magnetic portion,
when the case in a second closed position, the flexible member is offset from the first panel and the second magnetic portion engages the first magnetic portion, and
wherein a distance between the first panel and the second panel is greater when the case is in the second closed position than when the case is in the first closed position.

2. The universal case of claim 1, wherein the case further comprises:
a support structure coupled to the interior surface of the first panel and configured to engage the back side of the portable electronic device, and
wherein the first panel includes:
an upper section coupled to the support structure, and
a lower section pivotally coupled to the upper section, the lower section further pivotally coupled to the second panel at the closed end, and
wherein in a display position, the lower section is configured to pivot away from the support structure to support the support structure in an inclined position.

3. The universal case of claim 2, wherein in the inclined position, the support structure rests on the interior surface of the second panel.

4. The universal case of claim 3, wherein the interior of the second panel includes a high friction surface to contact the support structure in the inclined position.

5. The universal case of claim 3, wherein the interior of the second panel includes a groove to engage the support structure in the inclined position.

6. The universal case of claim 2, wherein the second panel further comprises first and second sections pivotally coupled to each other, and
wherein the pivotally coupled sections pivot into a stand to support the second panel and the support structure in an inclined position.

7. The universal case of claim 2, wherein the support structure includes an adhesive to engage a rear side of a portable electronic device.

8. The universal case of claim 2, wherein the support structure includes a rotational member to enable rotation of a secured portable electronic device from landscape to portrait orientations.

9. The universal case of claim 1, wherein the first and second magnetic portions each include at least one magnetic strip.

10. A case for a portable electronic device having a display side and a back side, the case comprising:
a rear panel including,
an interior surface to contact the portable electronic device,
an exterior surface,
an open edge, and
a first magnetic portion disposed adjacent the exterior surface and the open edge and having a length extending from the open edge;
a front panel pivotally coupled to the rear panel to transition the case from an open position to a closed position wherein the portable electronic device is disposed between the rear and front panels;
a flexible member coupled to the front panel; and
a flap pivotally coupled to the flexible member, the flap including a second magnetic portion having a second length less than the first length and the second length extending from the flexible member, the second magnetic portion configured to enable slidable engagement along the first length of the first magnetic portion,
when the case is in a first closed position, the flexible member at least partially overlaps the rear panel and the second magnetic portion engages the first magnetic portion,
when the case in a second closed position, the flexible member is offset from the rear panel and the second magnetic portion engages the first magnetic portion, and
wherein a distance between the rear panel and the front panel is greater when the case is in the second closed position than when the case is in the first closed position.

11. The universal case of claim 10, wherein the case further comprises:
a support structure coupled to the interior surface of the rear panel and configured to engage the back side of the portable electronic device, and
wherein the rear panel includes:
an upper section coupled to the support structure, and
a lower section pivotally coupled to the upper section, the lower section further pivotally coupled to the front panel at the closed end, and
wherein in a display position, the lower section is configured to pivot away from the support structure to support the support structure in an inclined position.

12. The universal case of claim 11, wherein in the inclined position, the support structure rests on the interior surface of the front panel.

13. The universal case of claim 12, wherein the interior of the front panel includes a high friction surface to contact the support structure in the inclined position.

14. The universal case of claim 12, wherein the interior of the front panel includes a groove to engage the support structure in the inclined position.

15. The universal case of claim 11, wherein the front panel further comprises first and second sections pivotally coupled to each other, and
wherein the pivotally coupled sections pivot into a stand to support the front panel and the support structure in an inclined position.

16. The universal case of claim 11, wherein the support structure includes an adhesive to engage a rear side of a portable electronic device.

17. The universal case of claim 11, wherein the support structure includes a rotational member to enable rotation of a secured portable electronic device from landscape to portrait orientations.

18. The universal case of claim 11, wherein the first and second magnetic portions each include at least one magnetic strip.
